(19) United States
(12) Patent Application Publication
(10) Pub. No.: US 2004/0142207 A1
(43) Pub. Date: Jul. 22, 2004

(54) Organic electoluminescent device with improved performance

(76) Inventor: Wen-Chun Wang, Taichung City (TW)

Correspondence Address: SUPREME PATENT SERVICES, POST OFFICE BOX 2339, SARATOGA, CA, 95070, US

(21) Appl. No.: 10/346,948

(22) Filed: Jan. 17, 2003

(51) Int. Cl. H05B 33/12

(52) U.S. Cl. 428/690; 428/917; 313/504; 313/506

(57) ABSTRACT

The present invention relates to an organic electroluminescent device comprising a mixed organic electroluminescent layer Ax′ By′ Cz inserted between the anode side and the cathode side, wherein A, B, and C are components capable of transporting holes, electrons and hole blocking component respectively, and x′ represents the content of A component, y′ represents the content of B component, and z represents the content of C component. The sum of x′, y′, and z is 100%. The component C is a hole blocking component comprising an organic medium with high ionization potential and high electron affinity.

### FIELD OF THE INVENTION

The present invention pertains to organic electroluminescent device, and more specifically to a structure that combines a mixing hole blocking medium for improving the illumination performance of the organic electroluminescent device.

### BACKGROUND OF THE INVENTION

In recent progress of organic electroluminescent device (OLED), the organic EL devices are attractive owing to the merits of high brightness, wide view angle, low driving voltage and capability for full color flat portable emissive displays. The normal organic electroluminescent device is generally composed of multi-layers of organic film sandwitched between two electrodes. The organic layer composes hole transporting layer, electroluminescent layer and electron transporting layer. Either the electron transporting layer or the hole transporting layer can be designed as the luminescent layer and the light can be transmitted either way but generally exits through one of the conductive layers. There are many methods to modify one of the conductive layers for the emission of light there through but it has been observed that the most efficient OELD includes one conductive layer, which is transparent to the light being emitted. The widely used material for this conductive and transparent layer is indium-tin-oxide (ITO), which is usually deposited on a transparent substrate, for example, the glass plate.

Although the multi-layers structure is normally used in constructing the organic electroluminescent devices but the interface between the electron transporting layer and hole transporting layer is sometimes not compatible and results a bad junction in the interface of the different layers. In another respect, the lifetime of multi-layered organic electroluminescent devices may be influenced by the abrupt change of interfaces between the hole and the electron transporting layers when the organic EL device is under voltage bias. So, some significant improvements in structure of electroluminescent device have been achieved in the prior art (See U.S. Pat. No. 5,925,980, U.S. Pat. No. 6,130,001). In these patents, a structure of electroluminescent device (U.S. Pat. No. 5,925,980) is provided which comprising a hole transporting region, an electron transporting region and a graduated region disseminated between the hole transporting region and the electron transporting region. The graduated region changes, either in steps or continuously, from hole transporting organic material adjacent the hole transporting region to electron transporting organic material adjacent the electron transporting region. In another structure (see U.S. Pat. No. 6,130,001), an organic electroluminescent layer is provided which comprises a continuous organic medium AxBy, where A and B are components capable of transporting electrons and holes, respectively, wherein x represents the content of A component with a value ranging from 0 adjacent the anode to 100% adjacent the cathode, and y represents the content of B component with a value ranging from 0 adjacent the cathode to 100% adjacent the anode. The lifetime of the above device is hence improved by the elimination of heterojunction of different layers.

Generally, there is always a need to provide a smooth reliable region so that the interface effect can be reduced to minima. However the smooth reliable region should not come at the expense of the efficiency of the organic electroluminescent device. So, further improvement was made and addressed in another patent (See U.S. Pat. No. 6,064,151). In this patent, the structure of organic electroluminescent device is provided which comprises an alkaline metal compound (AMC) doped region adjacent the cathode electrode. The additional medium AMC dopants can effectively reduce the barrier height such that the electron injection and transportation from electrode cathode to the organic doped electroluminescent region become easy. The reduced barrier height facilitates the injecting and transporting of electrons and thus promoting the efficiency of electron transporting efficiency from cathode to the doped electroluminescent region underneath. However, there are some drawbacks in the structure for some practical application, the organic elements, which acts as the host of AMC doped region, are organic medium mixed with electron transporting material and hole transporting material. The AMC doped region facilitates the injecting and transporting of electrons indeed, and the transporting efficiency of holes is also improved due to the existence of hole transporting material in AMC doped region. But as a consequence, this also brings a drawback that is unfavorable to the luminance efficiency of the device, because under this circumstance, both holes and electrons are not easy to be confined in or near the doped electroluminescent region in order to raise the possibility of carrier recombination.

Accordingly, it is the purpose of the present invention to provide a new organic electroluminescent device to enhance electron injection and transportation and to achieve high luminance efficiency simultaneously by confining the electrons and holes adjacent the organic electroluminescent region.

It is still another purpose of the present invention to provide a new organic electroluminescent device with improved lifetime and stability.

### SUMMARY OF THE INVENTION

The above problems and others are at least partially solved and the above purposes and others are realized in an organic electroluminescent device comprising a mixed organic layer inserted between the AMC doped layer and the organic electroluminescent layer.

The mixed organic layer in this invention comprises three components, which including hole transporting material, electron transporting material, and hole blocking material. The composition for forming the mixed organic layer is Ax′ By′ Cz, wherein A is the component capable of transporting holes, B is the component capable of transporting electrons, C is the component capable of blocking holes and x′, y′, and z denote the content of component A, B, and C respectively. Furthermore, the content x′, y′, and z in component A, B, and C have the following characteristics: the sum of x′, y′, and z is 100%.

The component C is a hole blocking medium comprising an organic medium with high ionization potential and high electron affinity. The characteristic of high ionization potential makes holes blocked near the organic electroluminescent layer, and the characteristic of high electron affinity makes electrons transport easily from cathode to the organic electroluminescent layer. So both carriers (electron and hole) can be confined more firmly in the organic electroluminescent layer. In this way, the high carrier concentration results an efficient electron-hole collision capture recombination process, which leads to promoting the illumination efficiency of the electroluminescent device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 depicts a simplified sectional view of an organic electroluminescent device in this invention.

### DETAILED DESCRIPTION OF THE INVENTION

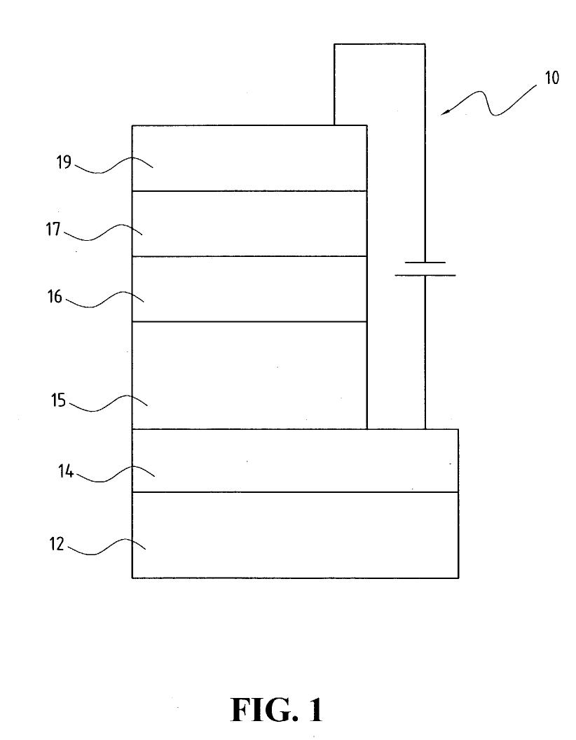

Referring now to FIG. 1, there is illustrated a simplified sectional view of an organic electroluminescent device 10 in accordance with the present invention. The organic electroluminescent device 10 is fabricated upon a substrate 12 in which it is transparent, in this preferred embodiment, and may be fabricated of any of the number of known materials employed in the art. For example, substrate 12 may be fabricated of a glass, such as Corning 7059 glass, transparent plastic substrate made of polyolefins, polyethersulfones, polyarylates, etc.

Deposited atop substrate 12 is an anode 14, which is conductive and optically transparent or semi-transparent. The material used for the anode 14 includes conductive metal oxides such as indium oxide, indium-tin oxide (ITO), zinc oxide, zinc-tin oxide, conductive transparent polymers such as polyaniline. The anode 14 can also be made as semi-transparent metal, which includes a thin layer (<500.ANG.) of gold, copper, silver, and combinations thereof.

Thereafter, atop the anode 14 is an organic electroluminescent layer 15 that comprises a mixed medium which is composed of mixed mediums AxBy, where A and B are components capable of transporting holes and electrons respectively, x represents the content of A component and y represents the content of B component. Either the A or the B can be designed to emit light and the light can be transmitted either way but generally exits through the conductive anode layers. For the purpose of enhancing the luminescent efficiency by efficient energy transferring, it is preferred that the fluorescent (or phosphorescent) dye or pigment with a bandgap no greater than that of AxBy medium is added, in which AxBy would act like a host, and the dye or pigment is uniformly doped within the AxBy medium. It is preferred that the dye or pigment is present in a concentration density of about 10⁻³ to 10 mole percent, based on AxBy medium mole content.

Deposited atop the organic electroluminescent layer 15 in the present invention is a mixed organic layer 16 inserted between the layer 15 and the electron injecting and transporting layer 17. In this embodiment, the mixed organic layer 16 is composed of three organic components. The layer 16 has a general formula of Ax′ By′ Cz wherein A component comprising the hole transporting material, B component comprising electron transporting material, C component comprising hole blocking material and x′, y′, and z denotes the content of the components A, B, and C respectively. Furthermore, the content x′, y′, and z in A, B, and C have the following characteristics:

The sum of x′, y′, and z is 100%. The component C is a hole blocking medium including an organic medium with high ionization potential (IP) and high electron affinity (Ea). The characteristic of high ionization potential makes holes blocked near the organic electroluminescent layer 15, and the characteristic of high electron affinity makes electrons easily transported from cathode to organic electroluminescent layer 15. So both carriers can be confined more firmly in the organic electroluminescent layer 15. High density of carrier concentrations in layer 15 results an efficient collision capture of electron-hole recombination process, which leads to luminance efficiency increase.

The content z of component C may lie within the range of 0% to 100%. In the extreme case, the content z of component C is 100%

The deposition materials for the structure are conducted by mixed evaporation technique through the valve release of different gases. Though components A, B, or C can be any one of hole transporting, electron transporting and hole blocking materials respectively, the preferred candidates for the materials are preferably as follows: the hole transporting material is preferably comprised of porphyrinic compound or organic tertiary aromatic amines. The electron transporting material is preferably selected from the group of organometallic complexes.

For the hole blocking material, it is preferably including an organic medium with high ionization potential and high electron affinity. In general, there's a well-established method to achieve high ionization potential and high electron affinity by attachment of groups in organic material such as nitro, carbonyl, cyano, metal complex of quinoline, oxadiazole, quinoxanline, and silole derivatives, and other organic material such as BCP.

Deposited atop the mixed organic layer 16 is an electron injecting and transporting layer 17 inserted between the mixed organic layer 16 and the cathode layer 19. It will be understood that the electron injecting and transporting layer 17 maybe either an AMC doped layer or a low work function metal such as Li, Ca, Mg or compounds such as LiF, LiO₂, or MgF₂ or metal alloys such as Li—Al, Ca—Al, Mg—Al.

The material used for fabrication of the cathode 19 is typically formed of a metal with a work function less than 4 eV. The material for the low work function is selected from a group of lithium, magnesium, calcium, or strontium while the preferred high work function metal is selected from a group of aluminum, indium, copper, gold, or silver. Alternatively, the cathode can be made of an alloy of a lower work function metal and a higher work function metal by evaporation technical to deposit the required materials.

While the preferred embodiment includes a transparent substrate and anode, it will be understood by those skilled in the art that the entire structure could be reversed so that the light is emitted upwardly in FIG. 1 and the substrate could then be opaque material.

In this embodiment, generally, the hole transporting, electron transporting, hole blocking materials are deposited on a surface by any of the well known evaporation or sputtering techniques. A typical example, substrate 12 is positioned in an evaporation chamber (not shown). A source of electron transporting organic material, a source of hole blocking material, and a source of hole transporting organic material are positioned sequentially in the evaporation chamber. In this preferred embodiment the three sources are put in separate containers, which can be continuously opened or closed.

Accordingly, a new and improved method has been disclosed for fabricating a new organic layer. While evaporation coating is presently the primary method for depositing these materials, it will be understood by those skilled in the art that the present method applies to any other techniques (e.g. sputtering), which might be utilized or devised.

While we have shown and described specific embodiments of the present invention, further modifications and improvements will occur to those skilled in the art. We desire it to be understood, therefore, that this invention is not limited to the particular forms shown and we intend in the appended claims to cover all modifications that do not depart from the spirit and scope of this invention.

What is claimed is:

1. An organic electroluminescent device comprising:
an anode electrode and an cathode electrode;
an organic electroluminescent layer positioned between said anode electrode and said cathode electrode wherein said organic electroluminescent layer defining an electroluminescent region;
a mixed organic layer positioned between said cathode electrode and said organic electroluminescent layer; and
an electron injecting and transporting layer positioned between said cathode electrode and said mixed organic layer.

2. An organic electroluminescent device as claim 1, wherein said organic electroluminescent layer is a mixed medium with a formula of AxBy wherein said A comprising the hole transporting material, said B comprising electron transporting material, and x, y denote the content of said medium A, B, respectively.

3. An organic electroluminescent device as claim 2, wherein the sum of said x and y is 100%.

4. An organic electroluminescent device as claim 2, wherein said organic electroluminescent layer with the formula of AxBy comprises at least one fluorescent, phosphorescent dye or pigment.

5. An organic electroluminescent device as claim 2, wherein said hole transporting material comprising a porphyrinic compound or organic tertiary aromatic amines.

6. An organic electroluminescent device as claim 2, wherein said electron transporting materials is selected from the group of organometallic complexes.

7. An organic electroluminescent device as claim 1, wherein said mixed organic layer is a mixed medium with a formula of Ax′ By′ Cz wherein said A comprises the hole transporting material, said B comprising comprises electron transporting material, said C comprises hole blocking material and x′, y′, and z denote the content of said components A, B and C, respectively.

8. An organic electroluminescent device as claim 7, wherein the sum of said x′, y′ and z is 100%.

9. An organic electroluminescent device as claim 7, wherein said hole transporting material comprises a porphyrinic compound or organic tertiary aromatic amines.

10. An organic electroluminescent device as claim 7, wherein said electron transporting materials is selected from the group of organometallic complexes.

11. An organic electroluminescent device as claim 7, wherein said hole blocking materials is an organic medium with high ion potential and high electron affinity and low hole mobility.

12. An organic electroluminescent device as claim 11, wherein said hole blocking materials include groups such as nitro, carbonyl, cyano, metal complex of quinoline, oxadiazole, quinoxanline, silole derivatives, and other organic material such as BCP.

13. An organic electroluminescent device as claim 1, wherein said electron injecting and transporting layer comprises AMC dopants.

14. An organic electroluminescent device as claim 1, wherein said electron injecting and transporting layer comprises low work function metal material such as Li, Ca, Mg, metal alloy such as Li—Al, Ca—Al, Mg—Al, and metal compound such as LiF, LiO₂, or MgF₂.

15. An organic electroluminescent device as claim 1, wherein said cathode is selected from a group of lithium, magnesium, calcium, or strontium.

16. An organic electroluminescent device as claim 1, wherein said cathode is selected from a group of aluminum, indium, copper, gold, or silver.

17. An organic electroluminescent device as claim 1, wherein said hole transporting, said electron transporting, and said hole blocking materials are deposited on a surface by any of the well known mixed evaporation techniques.
